(19) United States
(12) Patent Application Publication
(10) Pub. No.: US 2025/0314602 A1
(43) Pub. Date: Oct. 9, 2025

(54) METHOD FOR QUALIFYING A DEFECT STRUCTURE ON AN OBJECT UTILIZABLE IN PROJECTION LITHOGRAPHY

(71) Applicant: Carl Zeiss SMT GmbH, Oberkochen (DE)

(72) Inventors: Renzo Capelli, Heidenheim (DE); Klaus Gwosch, Aalen (DE); Michael Mohn, Ulm (DE); Armin Galetzka, Darmstadt (DE)

(21) Appl. No.: 19/097,257

(22) Filed: Apr. 1, 2025

(30) Foreign Application Priority Data
Apr. 9, 2024 (DE) 102024203208.5

(51) Int. Cl. G01N 21/95; G01B 11/24; G03F 7/00

(52) U.S. Cl. CPC G01N 21/9501; G01B 11/24; G03F 7/7065; G03F 7/706837

(57) ABSTRACT

To qualify a defect structure on an object utilizable in projection lithography, a target contour of at least one structure to be measured is first specified on the object. Furthermore, an actual contour of the structure is measured. A deviation between the target contour and the actual contour is determined perpendicularly to the profile of the target contour. A specified value of the determined deviation is documented as a defect qualification parameter of the structure to be measured. A further qualification method can dispense with a specified target contour. The respective qualification method enhances the significance of a defect qualification, which can be carried out in particular with a metrology system.

### CROSS-REFERENCE TO RELATED APPLICATION

The present patent application claims the priority to German patent application DE 10 2024 203 208.5, filed on Apr. 9, 2024, the entire content of which is incorporated by reference herein.

### TECHNICAL FIELD

The invention relates to a method for qualifying a defect structure on an object utilizable in projection lithography.

### BACKGROUND

A metrology system as known from US 2017/0131528 A1 (parallel document WO 2016/012425 A2), from WO 2016/012426 A1, from US 2017/0132782 A1 and from DE 10 2009 016 858 B4 is used to analyse defects of a structured component in the form of a reticle or a lithography mask in particular. Disclosed in US 2022/0229374 A1 is a method for determining a characteristic of a structure-forming process.

### SUMMARY

It is an aspect of the present invention to enhance the significance of a defect qualification, which is able to be carried out using a metrology system in particular.

This aspect is achieved in accordance with the invention by a method having the features specified in claim 1.

The object to be qualified with regard to the defect structure can be a structured component, for example a lithography mask or a reticle or else a potentially not yet structured component, for example a mask blank or a wafer blank. This means that the object can also be, for example, a wafer to be exposed or a wafer that has already been exposed.

Multilayer reflection layers and/or multilayer absorber layers can also represent objects to be qualified with regard to the defect structure.

In the determination step 35, a maximum part-field-actual difference can be determined, which corresponds to a predetermined multiple of a standard deviation of a normal distribution of the intensity distribution measured in the imaging of the structure-free ROI. The multiple of the standard deviation selected in the determination step 35 can be a multiple in the range between 1.5 and 5, especially in the range of 3.

The qualification method allows reproducible determination of deviations and documentation based on a reproducibly determinable defect qualification parameter. This can be utilized to separate compliant objects from waste. The specified value of the documented deviation can be a maximum value of the deviation. Alternatively, a mean deviation can be documented as a defect qualification parameter, whereby a weighted average can be used in particular.

Before determining the deviation between the target contour and the actual contour, the measured actual contour values, in particular the measured intensity values of the imaging light, can be normalized to the specified target values of the target contour when the actual structure of interest is being imaged. Systematic errors due to absolute value differences between the specified target values on the one hand and the measured actual values on the other can then be avoided.

The qualification method can be used for imaging wavelengths in the EUV range or else for other lithographic exposure wavelengths, especially in the DUV range. The qualification method can be used within the scope of aerial metrology or else within the scope of a SEM (Scanning Electron Microscope) image.

The qualification method can be used for a complete inspection, for example, of a lithography mask, to determine whether the lithography mask has defects. Alternatively or additionally, the qualification method can be carried out as part of a mask review, i.e. in the context of an investigation as to whether potential defects identified in a preliminary step represent actual defects or not.

In the qualification method according to the invention, the deviation is determined independently of the exact shape of the specified target contour. The qualification method can therefore be used for completely different target contours and is therefore generally applicable in this sense, regardless of the type and size of the specified target contour.

Specification variants for the target contour according to claims 2 to 4 have proven to be practical and can also be combined with each other depending on the present boundary conditions.

A specification of the target contour can also be specified by use of a simulated image of a defect-free structure to be imaged. A mask design of the reticle and/or mask or reticle parameters, for example materials and thicknesses of a layer structure of a mask or a coating, can be included in such a simulation.

A mean value specification of the target contour can, for example, take into account object roughnesses and error contributions.

It is a further aspect of the present invention to specify a significant qualification method also for cases in which a target contour of an object structure to be measured cannot be specified due to the lack of an ideally present structure.

This aspect is achieved in accordance with the invention by a method having the features specified in claim 5.

This further qualification method does not require a target contour specification. A defect results as a deviation between the maximum and minimum of an image intensity value and a respective part-field of the image field above a specified target difference. The measurement of the part-fields can be done by scanning the entire image field. In preparation, an ROI (region of interest) can be imaged, which is assumed to be defect-free. Based on the imaging result of a defect-free ROI of this type, the maximum target difference can then be specified, which is typically significantly greater than the difference between an intensity maximum and an intensity minimum when imaging the defect-free ROI. Alternatively, the maximum target difference in the initial specification step can also be calculated as a result of an estimation of typically expected difference values or based on a simulation.

In the further method, the defect structure is the sum of those part-fields in which the intensity difference between the maximum and the minimum imaging intensity value is greater than the target difference, thus in which there is an excessive intensity fluctuation. Such a defect structure can arise, for example, due to an unwanted particle deposit on the object to be qualified. For example, coating defects or material or micro-structure defects, in particular of a semiconductor material, can cause corresponding intensity deviations beyond the specified target difference. Other object faults that do not manifest themselves as a deviation from a target contour can also be identified in this way.

A specification of the maximum target difference according to claim 6 can be made by use of empirical values for intensity noise values. In particular, a speckle noise can be utilized as an intensity noise value. Contributions to the specification of the maximum target difference, in particular noise contributions, can be contributions of the metrology system, contributions of the object to be qualified, for example an object roughness, as well as metrology contributions, in particular of a detection device. Metrology system contributions beyond the detection device can arise, for example, from positioning errors and/or from drifts.

In a method according to claim 7, defect structures that are smaller than the specified minimum extent are not taken into account. The minimum extent is typically larger than a typical object roughness.

The advantages of a software product according to claim 8 correspond to those which have already been explained above with reference to the defect analysis method.

A corresponding statement applies to the advantages of a metrology system according to claim 9. The measurement light of the metrology system can have a wavelength in the EUV range, in particular in the range between 5 nm and 30 nm, for example of 13.5 nm. Alternatively, the metrology system can also operate using measurement light in the DUV range, for example measurement light at a wavelength of 193 nm or 248 nm.

Component parts of the metrology system may comprise a light source for illumination and imaging light, an illumination optical unit for illuminating an object field, an imaging optical unit for imaging the object field into an image field and a spatially resolving detection device for detecting an illumination intensity distribution within the image field. The metrology system can also include an open-loop/closed-loop control device. The open-loop/closed-loop control device can be used to perform the individual steps of the respective qualification method.

The metrology system can be used to measure a lithography mask provided for projection exposure for producing semiconductor components with a very high structure resolution, which is better than 500 nm, for example, or better than 100 nm and which can be better than 30 nm and better than 10 nm, in particular.

### BRIEF DESCRIPTION OF THE DRAWINGS

An exemplary embodiment of the invention will be explained in more detail below with reference to the drawing, in which:

FIG. 1 schematically shows a metrology system for carrying out a defect analysis with the aid of a determination of a production aerial image of an object to be measured, as a result of illuminating and imaging under illumination and imaging conditions corresponding to those of an optical production system, whereby a plan view of an object field and a plan view of a measurement or image field in a current z-position are additionally shown;

FIG. 2 shows in a plan view a fragment of an imaging intensity measurement result within the measurement field with an illustrated, round, defect-free structure object in the form of a semiconductor column, wherein a predetermined target contour of the structure object, which runs along an imaging intensity isoline, is highlighted in dashed lines;

FIG. 3 shows in an illustration similar to FIG. 2, a defect structure object which in comparison to the structure object according to FIG. 2 is deformed with respect to its contour, wherein an actual contour of the defect structure object, which runs along a figure intensity isoline, is highlighted by solid lines;

FIG. 4 shows a superimposition of the top views according to FIGS. 2 and 3 to illustrate a deviation between the target contour according to FIG. 2 and the actual contour according to FIG. 3, and a defect qualification parameter of the structure object to be measured resulting from this deviation, wherein in addition a difference of the imaging intensities according to FIGS. 2 and 3 is illustrated;

FIG. 5 shows a schematic sequence of a method for qualifying a defect structure, for example the defect structure according to FIG. 3, on an object utilizable in projection lithography, for example a lithography mask or a blank;

FIG. 6 shows, in a representation similar to FIG. 2, another measured structure object in the form of a defect-free line structure, wherein a vertically extending line-shaped elevation is shown centrally, to which a line-shaped depression is in each case shown adjacent to the right and left, in turn, a nominal contour of the line structure in the form of imaging intensity isolines in the region of flanks being highlighted in dashed lines between an elevation and a depression adjacent to the latter;

FIG. 7 shows in an illustration similar to FIG. 6 a corresponding line structure with a defect structure in a central region of a delimitation, on the right side in FIG. 7, of the linear elevation illustrated in the centre, wherein an actual contour in particular of this defect structure is highlighted by solid lines in FIG. 7;

FIG. 8 shows in an illustration similar to FIG. 4 a superimposition of the contour illustrations according to FIGS. 6 and 7, again to visualize a defect qualification parameter of the line structure to be measured, documenting a deviation between the target contour and the actual contour;

FIG. 9 shows in an illustration similar to FIG. 5 a schematic sequence of a further method for qualifying a defect structure, without a target contour being utilizable in this case, as an alternative or additionally utilizable qualification method;

FIG. 10 shows an imaging intensity measurement result when imaging a structure-free region of interest (ROI) of an object to be measured for the preparation of a defect-independent specification of a maximum target difference between an imaging intensity maximum and an imaging intensity minimum in the context of the qualification method according to FIG. 9;

FIG. 11 shows an imaged ROI with a defect structure defined in the context of the qualification method according to FIG. 9; and

FIG. 12 shows in an illustration similar to FIGS. 4 and 8 a superimposed illustration for visualizing a defect qualification parameter documenting a deviation between a target contour and an actual contour of an array structure to be measured.

### DETAILED DESCRIPTION

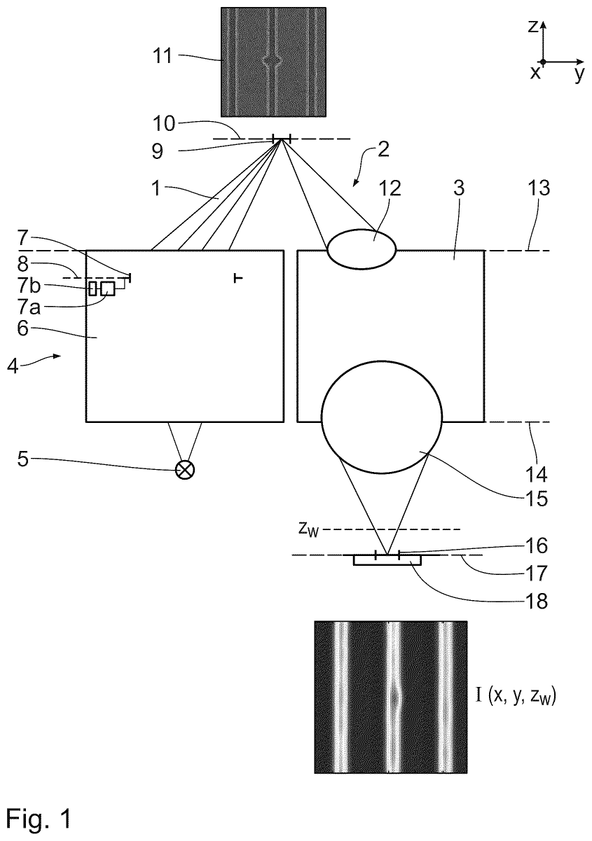

FIG. 1 shows, in a plane corresponding to a meridional section, a beam path of EUV illumination light or EUV imaging light 1 in a metrology system 2 having an imaging optical unit 3 which is schematically reproduced by a box in FIG. 1. The imaging optical unit 3 includes a plurality of mirrors to guide the EUV imaging light 1. The imaging optical unit 3 may be embodied as a projection objective in particular having two to six mirrors. The illumination light 1 is generated in an illumination system 4 of the projection exposure apparatus 2.

The metrology system 2 is described hereinafter using the example of a EUV metrology system. Depending on the requirements placed on metrology, the metrology system can also be used as a DUV metrology system with a measurement light wavelength of 193 nm or 248 nm, for example.

In order to facilitate the illustration of relative positions, a Cartesian xyz-coordinate system will be used hereinafter. The x-axis in FIG. 1 runs perpendicularly to the plane of the drawing and out of the latter. The y-axis in FIG. 1 runs towards the right. The z-axis in FIG. 1 runs upwards.

The illumination system 4 contains an EUV or DUV light source 5 and an illumination optical unit 6, depicted schematically in each case. The illumination optical unit 6 includes a plurality of mirrors to guide the EUV illumination light 1. Alternatively or in addition to at least one mirror, the illumination optical unit 6 may include a beam mixing unit being embodied in particular as at least one hollow waveguide and/or being embodied as at least one facet mirror or MEMS device with a plurality of micro mirrors.

The light source can be a laser plasma source (LPP; laser produced plasma) or a discharge source (DPP; discharge produced plasma). In principle, a synchrotron-based light source can also be used, for example a free electron laser (FEL). A utilizable wavelength of the illumination light 1 can lie in the range of between 5 nm and 30 nm. In principle, in the case of a variant of the metrology system 2, it is also possible to use a light source for another utilizable light wavelength, for example for a utilizable wavelength of 193 nm or of 248 nm.

The illumination light 1 is conditioned in the illumination optical unit 6 of the illumination system 4 in such a way that a specific illumination setting of the illumination, which is to say a specific illumination angle distribution, is provided. Said illumination setting corresponds to a specific intensity distribution of the illumination light 1 in an illumination pupil of the illumination optical unit of the illumination system 4. A pupil stop 7 disposed in a pupil plane 8 of the illumination optical unit 6 serves to provide the respective illumination setting.

The pupil stop 7 is held in a stop holder 7a. This may be a quick-change stop holder which enables a replacement of the pupil stop 7 currently used in the illumination with at least one change pupil stop. Such a quick-change holder may comprise a cartridge having a plurality of pupil stops 7, in particular different pupil stops, for specifying various illumination settings.

The stop holder 7a can be displaceable by a stop displacement drive 7b, also schematically indicated in FIG. 1, for displacing the pupil stop 7 in the pupil plane 8 in a displacement direction, on the one hand, or else in two displacement directions which are mutually perpendicular, on the other hand. Alternatively or additionally, the stop displacement drive 7b may be designed such that a displacement of the pupil stop 7 perpendicular to the pupil plane 8, i.e. along the z direction, is possible.

In some implementations, an image-proximal numerical aperture of the imaging optical unit 3 is 0.7. Depending on the embodiment of the imaging optical unit 3, the image-proximal numerical aperture is greater than 0.5 and may also be 0.55, 0.6, 0.65, 0.75, 0.8 or even more. This image-proximal numerical aperture of the imaging optical unit 3 is adapted to the image-proximal numerical aperture of the production projection exposure apparatus to be simulated by the imaging by the metrology system. Accordingly, the illumination setting set by the dipole pupil stop 7 is also adapted to a production illumination setting of this production projection exposure apparatus.

The metrology system 2 is used as follows: First, the imaging optical unit 3 on the one hand and—by way of the respective pupil stop 7, or by setting the stop displacement drive 7b, on the other hand—an image-proximal numerical aperture and an illumination setting are set, these corresponding to the illuminating and imaging conditions of a production projection exposure apparatus to be measured.

With the illumination setting that is respectively set, the illumination light 1 illuminates an object field 9 of an object plane 10 of the metrology system 2. Thus, a lithography mask 11, which is also referred to as a reticle, is arranged in the object plane 10 as an object to be illuminated during the production as well. The lithography mask 11 represents the object in the form of a structured component which should be measured using the metrology system 2. The metrology system 2 is used to carry out a defect analysis of the lithography mask 11. The defect analysis is implemented with the aid of aerial image measurement by the metrology system 2. For example, the metrology system 2 can include one or more computers configured to perform the defect analysis.

A structure portion of the lithography mask 11 is shown schematically in an insert above the object plane 10, which extends parallel to the xy-plane, in FIG. 1. This structure portion is illustrated in such a way that it lies in the plane of the drawing in FIG. 1. The actual arrangement of the lithography mask 11 is perpendicular to the plane of the drawing of FIG. 1 in the object plane 10.

The illumination light 1 is reflected from the lithography mask 11, as schematically illustrated in FIG. 1, and enters an entrance pupil 12 of the imaging optical unit 3 in an entrance pupil plane 13. The utilized entrance pupil 12 of the imaging optical unit 3 is round or, as schematically indicated in FIG. 1, has an elliptic periphery.

Within the imaging optical unit 3, the illumination or imaging light 1 propagates between the entrance pupil plane 13 and an exit pupil plane 14. A circular exit pupil 15 of the imaging optical unit 3 lies in the exit pupil plane 14. The imaging optical unit 3 can be anamorphic and generates the circular exit pupil 15 from the round or elliptic entrance pupil 12.

The imaging optical unit 3 images the object field 9 into a measurement or image field 16 in an image plane 17 of the projection exposure apparatus 2. In an insert below the image plane 17, FIG. 1 schematically shows an imaging light intensity distribution I which is measured in a plane spaced apart from the image plane 17 by a value z_{w} in the z-direction, which is to say an imaging light intensity at a defocus value z_{w}.

The imaging light intensities I (x, y, z_{w}) at the various z-values around the image plane 17 are also referred to as a 3D aerial image of the projection exposure apparatus 2.

A spatially resolving detection device 18, which can be a charge coupled device (CCD) camera or a complementary metal-oxide-semiconductor (CMOS) camera, is arranged in the image plane 17, which represents a measurement plane of the metrology system 2. The detection device 18 registers the imaging light intensities I(x, y, z_{w}). For example, one or more computers of the metrology system 2 can be configured to process data representing the imaging light intensities registered by the detection device 18.

The imaging optical unit 3 may have a magnifying imaging scale greater than 100 when imaging the object field 9 into the image field 16. This imaging scale can be greater than 200, can be greater than 250, can be greater than 300, can be greater than 400, and can be greater than 500. The imaging scale of the imaging optical unit 3 is typically less than 2000.

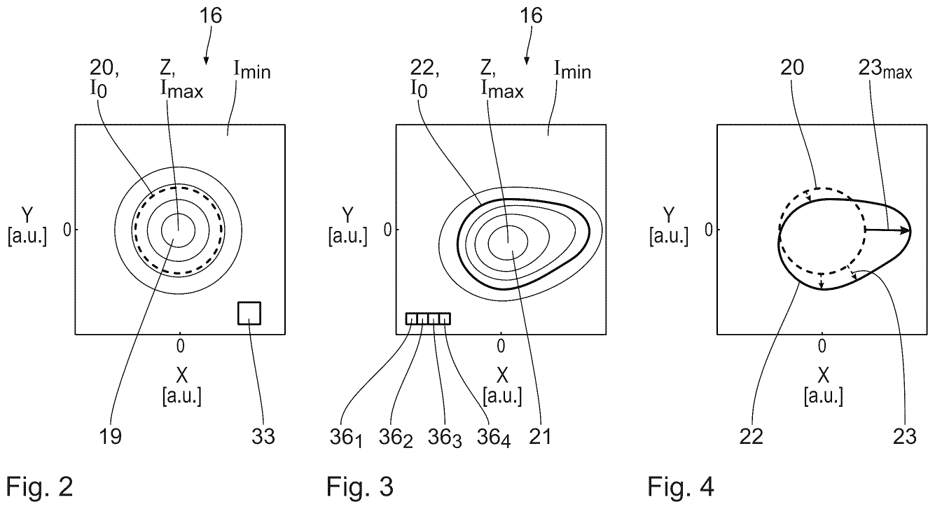

FIG. 2 shows in an enlarged fragment an exemplary portion of the image field 16 with a structure image 19 of a structure to be measured on the reticle 11 shown as the intensity profile of the image light 1. The intensity profile of the structure image 19 has the greatest intensity Iₘₐₓ in the centre of FIG. 2, which decreases rotationally symmetrically continuously outwards to a value Iₘᵢₙ present on the periphery.

In FIG. 2, a round target contour 20 of the structure image 19 is highlighted by a dashed line. The structure image 19 is the structure image of a defect-free object structure. This defect-free object structure can have been determined in the context of a preliminary inspection. Such preliminary inspection may be performed by a preliminary inspection unit which may be part of the metrology system or, in a different embodiment, may be a unit which is independent of the metrology system. The preliminary inspection unit may be a scanning electron microscope (SEM). The preliminary inspection of the reticle 11 includes the determination of the structure image 19. Further, the preliminary inspection of the reticle 11 can include specifying the target contour 20 of the structure to be measured on the reticle 11. Alternatively or in addition, the preliminary inspection unit may be realized by a preliminary imaging optical unit corresponding to the imaging optical unit 3.

The target contour 20 follows an intensity isoline of the intensity profile of the structure image 19, i.e. the image of a corresponding round object structure of the reticle 11. For example, one or more computers of the metrology system 2 can be configured to process the structure image 19 to determine the intensity isoline and the target contour 20. This object structure can be a column structure with a diameter in the range between 10 nm and 100 nm.

FIG. 3 shows in an illustration similar to FIG. 2 again a fragment of the image field 16 with a further imaged structure image 21 of a defect structure.

In FIG. 3, an actual contour 22 of the defect structure image 21 is highlighted by a solid line, which in turn runs along an isoline of the image intensity over the portion of the image field 16.

For example, one or more computers of the metrology system 2 can be configured to process the defect structure image 21 to determine the intensity isoline and the actual contour 22.

Both isolines of the target curve 20 of the defect-free structure image 19 and of the actual contour 22 of the defect structure image 21 run at the same level of the relative intensity value I₀, which can be in the range between 0.2 and 0.8 Iₘₐₓ, depending on the specification, for example, at 0.3 Iₘₐₓ or even at 0.5 Iₘₐₓ.

FIG. 4 shows a superimposition of the defect-free target curve 20 (dashed) and the actual curve 22 of the defect structure (solid). Moreover illustrated in FIG. 4 is a deviation 23 between the target curve 20 and the actual curve 22 perpendicular to the profile of the target contour 20. This deviation 23 is also referred to as the Edge Placement Error. For example, one or more computers of the metrology system 2 can be configured to process the target curve 20 and the actual curve 22 to determine the deviation 23. The deviation 23 can be a series of vectors for each point on the target curve 20, each vector representing a deviation of the actual contour 22 from the target contour 20 at the point in the direction of the normal line so that the deviation 23 can be processed by a computer. The at least one computer of the metrology system 2 determines the deviation 23 by comparing the defect-free target curve 20 and the actual curve 22 of the defect structure image 21.

In this example, due to the round shape of the target contour 20, the deviation 23 runs in the radial direction. A maximum value 23ₘₐₓ of the deviation 23, i.e. a maximum deviation between the target curve 20 and the actual curve 22 perpendicular to the course of the target contour 20, is highlighted in FIG. 4. This maximum value of 23ₘₐₓ represents a defect qualification parameter of the defect structure to be measured with the defect structure image 21. Other possible defect qualification parameters are a delocalisation of a center of gravity of the actual curve 22 as compared to the target curve 20 in x and/or y coordinates. Further defect qualification parameters may be an area limited by the actual curve 22 as compared to the area limited by the target curve 20.

With respect to the imaging intensity values, FIG. 4 simultaneously illustrates a difference image between FIGS. 2 and 3. In the region of the deviation between the actual contour 22 and the target contour 20, the intensity difference illustrated in FIG. 4 has the absolutely largest value.

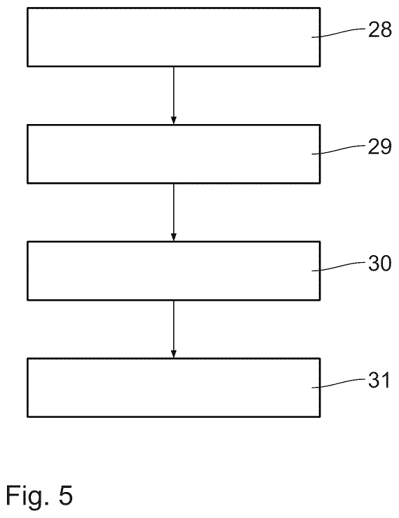

FIG. 5 visualizes a method for qualifying the defect structure with the defect structure image 21 on the reticle 11, thus on an object utilizable in projection lithography. For example, one or more computers of the metrology system 2 can implement the process of FIG. 5.

In a specification step 28 of the qualification method, the target contour 20 of the structure to be measured on the reticle 11 is specified. As explained above in conjunction with FIG. 2, this can be carried out in the context of a preliminary inspection of the reticle 11 by measuring the column structure qualified as defect-free in the context of the preliminary inspection with the structure image 19.

Alternatively, the target contour 20 can be specified as the mean value of a plurality of object structures measured in the context of a preliminary inspection of the reticle 11. All structures within a captured field (field of view) and/or all the same structures on the object, which are present within this acquired field as well as other selected acquired fields and have the same nominal shape and size of a given structure type, can be taken into account. It is not mandatory that all measured object structures are free of defects. Due to the averaging, this results in an improved statistical significance of the specified target contour.

Again, alternatively or additionally, the target contour 20 can be specified as a specified value of a structure result to be achieved by projection lithography, for example as a target image size “round structure with diameter 80 nm.” In addition, it can be taken into account that smooth or exact specified target contours practically do not appear in reality. A basic roughness, which occurs in real objects with the small captured length scales in the nm range, can be taken into account when specifying the target contour.

After specifying 28 the target contour 20, the (defect) structure to be measured is measured in a measuring step 29, wherein in the measuring step the actual contour 22 results as an isoline of the imaging intensity, as explained above in conjunction with FIG. 3.

In a subsequent determination step 30 of the qualification method, the deviation 23 between the target contour 20 and the actual contour 22 is determined perpendicularly to the profile of the target contour 20, as illustrated above by way of example by means of FIG. 4.

In a documentation step 31, the maximum value 23ₘₐₓ of deviation 23 is documented as a defect qualification parameter of the structure to be measured. For example, the maximum value 23ₘₐₓ of deviation 23 can be stored in a storage device, which can be a volatile or non-volatile storage device, such as random access memory (RAM), flash memory, hard disk drives, solid state drives, and optical discs.

The documented defect qualification parameter 23ₘₐₓ can be compared with a tolerance value 23₀ of the defect qualification parameter. If, for example, the result is 23ₘₐₓ>23₀, then the structure resulting from the defect structure image 21 according to FIG. 3 is qualified as a defective structure. If 23ₘₐₓ ≤23₀, the result of the qualification is that the structure object 21 deviates from the target value, but is still usable.

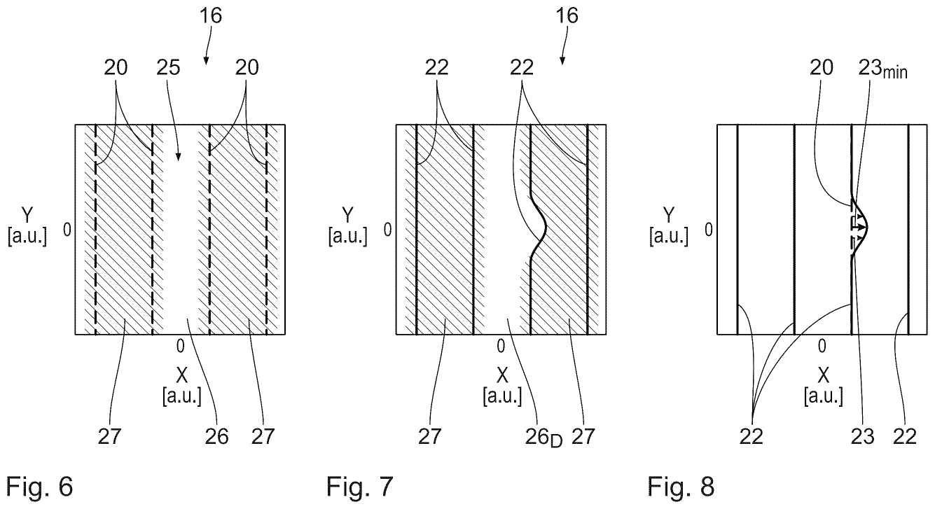

FIGS. 6 to 8 show, analogously to FIGS. 2 to 4 described above, the conditions in the qualification of a defect structure in relation to a defect-free line structure. Components and functions corresponding to those which have already been explained above with reference to FIGS. 2 to 4 bear the same reference signs and will not be discussed in detail again.

A defect-free line structure image 25 according to FIG. 6 has a plurality of structure elevations 26 which extend so as to be mutually equidistant in the y-direction and which represent the intensity maxima of an imaging intensity over the portion of the image field 16. One of these structure elevations 26 extends centrically in FIG. 6, at the x-value 0.

Between the structure elevations, whose x-distance can be in the range between 10 nm and, for example, 200 nm, are structure depressions 27 which also extend along the y-direction.

Target contours 20, which represent boundary lines between the respective structure elevation 26 and the adjacent structure depression 27, again extend along the y-direction, as explained above with reference in particular to FIGS. 2 and 3, along image intensity isolines. In contrast to the example according to FIG. 2, the target contours 20 are not closed due to the linear structures.

FIG. 7 shows analogously to FIG. 3 actual contours 22 of a central structure elevation 26 with a defect in the positive x-direction at y=0. Apart from a defect region, which manifests itself there as a bulge with an increased x-structure increase width, the actual curves 22 extend on the target curves 20 according to FIG. 6.

FIG. 8 shows in an illustration corresponding to FIG. 4 the superimposition of the target curves 20 according to FIG. 6 with the actual curves 22 according to FIG. 7, the deviation 23 including the maximum deviation value 23ₘₐₓ again being illustrated. The deviation 23 also extends perpendicularly to the profile of the target contour 20 in FIG. 8 (dashed in FIG. 8).

The qualification method explained above with reference to FIG. 5 is used in the same manner as explained above in conjunction with the curves 20, 22 according to FIGS. 2 to 4, also in the curves 20, 22 of FIGS. 6 to 8.

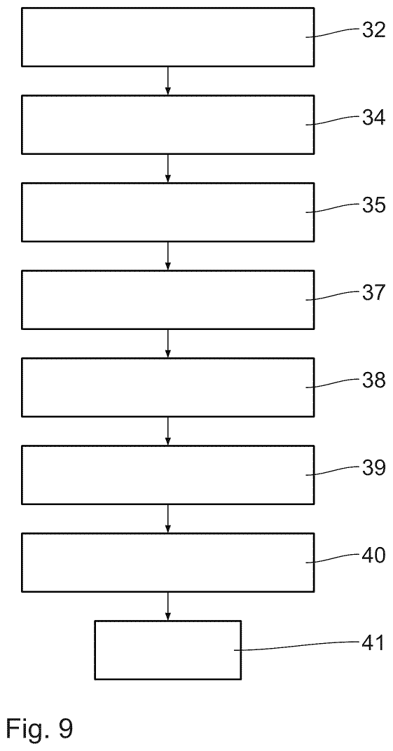

If no target contour is available, an alternative or additional method for qualifying a defect structure on the object utilizable in projection lithography can be used, which is explained below with reference to FIG. 9. Such defects without a specified target contour can, for example, be foreign particles that adhere to a surface which is particle-free in the desired case.

In the qualification method according to FIG. 9, a maximum target difference between an intensity maximum Iₘₐₓ and an intensity minimum Iₘᵢₙ of an intensity measured value is initially specified as a tolerance limit in a specification step 32 when imaging a structure-free or defect structure-free region of interest (ROI) 33 of the reticle 11. Such a structure-free ROI 33 is indicated on the lower right in FIG. 2.

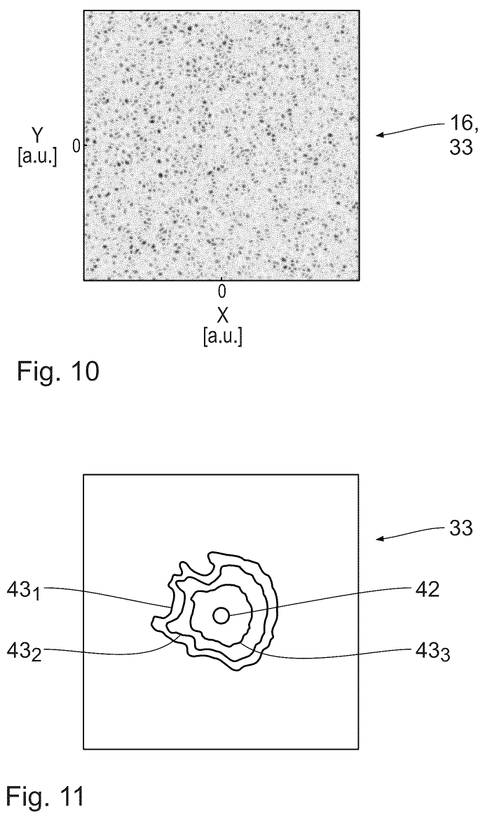

FIG. 10 shows by way of example an imaging result of the imaging of such a structure-free ROI 33. The imaged object 11 is a multi-layer reflective object, which is partially coherently illuminated with the illumination light 1 via the object field 9. The ROI 33 represents a portion of the image field 16, or else the entire image field 16. In the image of the structure-free ROI 33, a typical speckle pattern of the imaging intensity results, which varies in the example according to FIG. 10 between the relative intensity values 0.9 and 1.08.

FIG. 11 shows in a difference illustration comparable to FIGS. 4 and 8 an intensity difference between a currently interesting ROI 33 with a defect structure in the form of a structure image 42 (range of maximum defect intensity) and the defect-free intensity image according to FIGS. 10. At 431, 432 and 433, three examples of periphery contours 43; of the defect structure pertaining to the structure image 42 are illustrated in FIG. 11 as intensity isolines, which result from the implementation of the qualification method according to FIG. 9 as a result of various part-field-actual differences (e.g. multiples of a standard deviation o of a normal distribution of the image intensity of the defect-free ROI 33 according to FIG. 10). Part-fields and a part-field actual difference which are used in the qualification method hereinafter are explained with respect to a determination step 35.

The periphery contour 431 results at the smallest predetermined part-field-actual difference (e.g. 30), so that the resulting periphery contour 431 of the resulting defect structure occupies the largest surface as a result of the definition step 38. The further periphery contours 432 and 433 are the result of the implementation of the qualification method according to FIG. 9 with gradually larger maximum part-field-actual difference specified in the determination step 35 (e.g. 2σ and 1σ).

The result is a respective periphery contour 43; of the qualified defect structure, from which the comparison 37 and the definition 38 can be used, for example, to conclude on the presence of a particle and in particular a particle type.

In ROI 33, there are, for example due to contributions of the metrology system 2, due to contributions of the object to be measured, i.e., for example, due to a roughness of a structure-free area of the reticle 11 or a roughness of a blank, or else due to contributions of the detection device 18, intensity differences of the imaging intensity, which lead to an intensity difference between an intensity maximum Iₘₐₓ and an intensity minimum Iₘᵢₙ within the ROI. A maximum permissible target difference between Iₘₐₓ and Iₘᵢₙ is specified as the maximum target difference in the specification step 32. The maximum target difference can be specified in particular on the basis of an intensity-noise value.

Subsequently, in an imaging step 34 of the qualification method, an imaging of the ROI 33 or another selected region of interest is performed for acquiring an image field corresponding to the ROI 33 with intensity measurement values that are assigned to the image field points 16; within the ROI 33.

In a determination step 35 of the qualification method, a maximum part-field actual difference (TID) is now determined. This is a difference between an intensity maximum Iₘₐₓ and an intensity minimum Iₘᵢₙ of the measured intensity value I in each case present in part-fields of the image field 16 when imaging the respective part-field of the image field 16. Such part-fields, which can be scanned in the context of a measurement scan within the image field 16, are reproduced in FIGS. 3 at 36₁ to 36₄ in the context of a part-field row extending in the x-direction.

In a comparison step 37 of the qualification method, the respective part-field actual differences are compared with the target difference specified in the specification step 32.

In a definition step 38, all part-fields 36ᵢ in which the part-field actual difference is greater than the target difference are defined as a defect structure.

In the case of the defect structure resulting in the context of the definition step 38, an extent measurement in the x-direction and/or in the y-direction can now be carried out. Such extent measurement refers to the measurement of a dimension of the qualified defect structure in x- and/or in y-direction. The unit of the measured extent is a length dimension, e.g., nanometer.

The measured extent of the defect may be for example the x extension of the defect structure or the y extension of the defect structure or the larger of these two extensions.

To prepare this extent measurement, a minimum extent of a then qualified defect structure is first specified. This is performed in a specification step 39 of the qualification method according to FIG. 9. This minimum extent is typically larger than, for example, a typical roughness of the object to be qualified. Such specification of the minimum extent of the then qualified defect structure ensures that no false positive defects due to the typical object roughness would be qualified. For example, the minimum extent may be specified to be ten times the typical roughness of the object to be qualified. In a preparation step, such typical roughness of the object may be measured via a corresponding roughness measurement unit.

In a comparison step 40, the defect structure defined in the definition step 38 is compared with the minimum extent specified in the specification step 39 with regard to its defect-structure extent.

In an output step 41, the defect structure defined in definition step 38 is output as a qualified defect structure if the defect structure defined in definition step 38 is greater than the minimum extent specified in specification step 39.

The qualification methods described above can manifest themselves as a software product on a storage medium.

A software algorithm for carrying out the defect qualification according to any one of the above-described methods can be designed as a computer program and be part of a computer program product which is stored on a computer-suitable medium and comprises computer-readable program means, which cause a computer to carry out the various steps of the defect qualification.

In some implementations, a computer can include one or more data processors. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

In some implementations, the computer program can be stored in one or more machine-readable storage devices, such as hard drives, magnetic disks, solid state drives, magneto-optical disks, or optical disks. Alternatively or in addition, the computer program can be encoded on a propagated signal that is an artificially generated signal, e.g., a machine-generated electrical, optical, or electromagnetic signal, that is generated to encode information for transmission to suitable receiver apparatus for execution by a programmable processor. The computer program can be written in any form of programming language, including compiled or interpreted languages, and it can be deployed in any form, including as a stand-alone program or as a module, component, subroutine, or other unit suitable for use in a computing environment.

In some implementations, the processes described above can be implemented using software for execution on one or more mobile computing devices, one or more local computing devices, and/or one or more remote computing devices (which can be, e.g., cloud computing devices). The processes can include, e.g., the process for qualifying the defect structure shown in FIG. 5, and the qualification process shown in FIG. 9. For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one data processor, at least one data storage system (including volatile and non-volatile memory and/or storage elements), at least one wired or wireless input device or port, and at least one wired or wireless output device or port.

The respective qualification method may be part of a measurement program which is carried out by the metrology system 2 for the examination of the respective object utilizable in projection lithography.

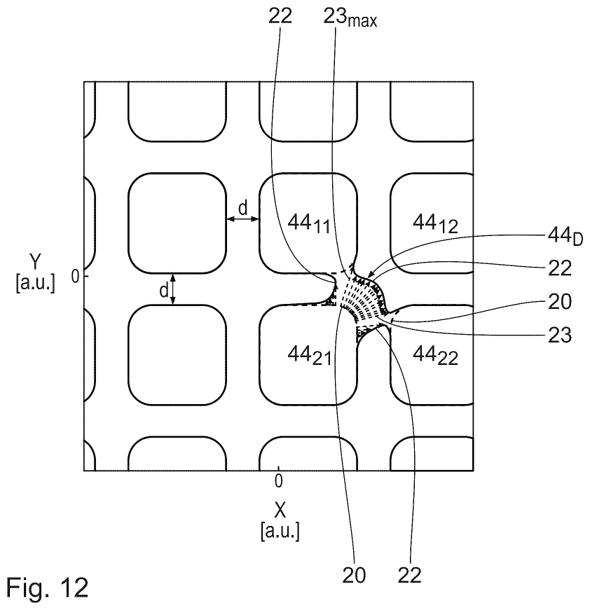

FIG. 12 shows another example of a deviation 23 between a target contour 20 and an actual contour 22 determined and documented by use of the method according to FIG. 5, using the example of a target contour 20 in the form of an X/Y array of structure squares 44ᵢⱼ with spherically radiused corners.

A defect structure manifests itself in the example of FIG. 12 as the convergence of three structure squares 44₁, 44₂₁ and 44₂₂ in such a manner that the adjacent structure squares 44₁₁ and 44₂₁ within a column, the structure squares 44₂₁ and 44₂₂ directly adjacent to one another within a row, and also the diagonally adjacent structure squares 44₁₁ and 44₂₂ within the array assembly of the structure squares 44ᵢⱼ, which in turn represent intensity isolines, are connected to one another undesirably via actual contours 22, i.e. are not separate from one other, as is the case with target contours 20. This convergence results in a defect structure 44_{D}.

Proceeding from the target contour 20 of the structure square 44₂₁, the deviation 23 between this target contour 20 and the actual contours 22 is determined in the determination step 30 of the qualification method according to FIG. 5.

A maximum value 23ₘₐₓ of the deviation 23 is in the example according to FIG. 12 greater than a row or column distance d of two adjacent structure squares 44ᵢⱼ. In the example according to FIG. 12, a fraction of this row-column distance d, for example d/2, d/4, d/8 or else d/10, can be used as a specified value for the determined deviation 23. Since in the example according to FIG. 12 23ₘₐₓ>d/2, the maximum deviation 23ₘₐₓ determined by the qualification method according to FIG. 5 is qualified as a defect structure, and the deviation value 23ₘₐₓ is qualified as a defect qualification parameter of the structure to be measured.

In some implementations, after the defective structures are qualified or identified, the lithography mask 11 (or another object whose defect structures are being qualified) is sent to a repair system to repair the defective structures. For example, the lithography mask repair system can be configured to perform an electron beam-induced etching and/or deposition on the mask. The repair system can include, e.g., an electron source, which emits an electron beam that can be used to perform electron beam-induced etching or deposition on the mask. The repair system can include mechanisms for deflecting, focusing and/or adapting the electron beam. The repair system can be configured such that the electron beam is able to be incident on a defined point of incidence on the mask.

The repair system can include one or more containers for providing one or more deposition gases, which can be guided to the mask via one or more appropriate gas lines. The repair system can also include one or more containers for providing one or more etching gases, which can be provided on the mask via one or more appropriate gas lines. Further, the repair system can include one or more containers for providing one or more additive gases that can be supplied to be added to the one or more deposition gases and/or the one or more etching gases.

The repair system can include a user interface to allow an operator to, e.g., operate the repair system and/or read out data. The repair system can include a computer unit configured to cause the repair system to perform one or more repair processes based at least in part on an execution of an appropriate computer program. The repair system can also repair other types of objects (e.g., wafers) having integrated circuit patterns.

In some implementations, a lithography mask can include 1×10³ to 1×10⁹ structures. A computer-implemented process for automatically (or partially automatically) qualifying the defective structures to allow automated (or partially automated) determination or identification of structures having defects that need to be repaired can greatly improve operation efficiency of the semiconductor manufacturing process.

Although the present invention is defined in the attached claims, it should be understood that the present invention can also be defined in accordance with the following embodiments:

Embodiment 1. Method for qualifying a defect structure (21; 26_{D}; 44_{D}) on an object (11) utilizable in projection lithography, comprising the following steps:
specifying (28) a target contour (20) of at least one structure (19; 26) to be measured on the object (11),
measuring (29) an actual contour (22) of the structure (21; 26_{D}; 44_{D}),
determining (30) a deviation (23) between the target contour (20) and the actual contour (22) perpendicularly to the profile of the target contour (20),
documenting (31) a specified value (23ₘₐₓ) of the determined deviation (23) as a defect qualification parameter of the structure (21; 26_{D}; 44_{D}) to be measured.

Embodiment 2. Method according to Embodiment 1, characterized in that the target contour (20) is specified in the context of a preliminary inspection of the object (11) by measuring a structure (19; 26; 44ᵢⱼ) which is qualified as defect-free in the context of the preliminary inspection.

Embodiment 3. Method according to Embodiment 1 or 2, characterized in that the target contour (20) is specified as the mean value of a plurality of object structures (19; 21; 26; 26_{D}; 44ᵢⱼ) measured in the context of a preliminary inspection of the object (11).

Embodiment 4. Method according to one of Embodiments 1 to 3, characterized in that the target contour (20) is specified as a specified value of a structure result to be achieved in the projection lithography.

Embodiment 5. Method for qualifying a defect structure on an object (11) utilizable in projection lithography, comprising the following steps:
specifying (32) a maximum target difference (Iₘₐₓ−Iₘᵢₙ) between an intensity maximum (Iₘₐₓ) and an intensity minimum (Iₘᵢₙ) of a measured intensity value (I) when imaging a ROI (33) of the object (11) as a tolerance limit,
imaging (34) the ROI (33) of the object (11) for detecting an image field (16) corresponding to the ROI (33), having measured intensity values (I) assigned to the image field points (16ᵢ),
determining (35) a maximum part-field actual difference between an intensity maximum and an intensity minimum of a measured intensity value, present in each case in part-fields (36ᵢ) of the image field (16), when imaging the respective part-field (36ᵢ),
comparing (37) the respective part-field actual difference with the target difference for all part-fields (36ᵢ),
defining (38) the defect structure (42; 43ᵢ) as the sum of all part-fields (36ᵢ) in which the part-field actual difference is greater than the target difference.

Embodiment 6. Method according to Embodiment 5, characterized in that the maximum target difference is surrounded based on an intensity noise value.

Embodiment 7. Method according to Embodiment 5 or 6, characterized by the following further steps:
specifying (39) a minimum extent of a qualified defect structure,
comparing (40) an extent of the defect structure with the specified minimum extent,
outputting (41) the defined defect structure as a qualified defect structure if the extent of the defined defect structure is greater than the minimum extent.

Embodiment 8. Software product for carrying out a program sequence corresponding to a method according to one of Embodiments 1 to 7.

Embodiment 9. Metrology system for carrying out a method according to one of Embodiments 1 to 7.

A number of implementations have been described. Nevertheless, it will be understood that various modifications may be made. For example, the elements of one or more implementations may be combined, deleted, modified, or supplemented to form further implementations. In addition, other components may be added to, or removed from, the described metrology system. Accordingly, other implementations are within the scope of the following claims.

What is claimed is:

1. A method for qualifying a defect structure on an object utilizable in projection lithography, comprising the following steps:
specifying a target contour of at least one structure to be measured on the object,
measuring an actual contour of the structure,
determining a deviation between the target contour and the actual contour perpendicularly to the profile of the target contour, and
documenting a specified value of the determined deviation as a defect qualification parameter of the structure to be measured.

2. The method according to claim 1, wherein the target contour is specified in the context of a preliminary inspection of the object by measuring a structure which is qualified as defect-free in the context of the preliminary inspection.

3. The method according to claim 1, wherein the target contour is specified as the mean value of a plurality of object structures measured in the context of a preliminary inspection of the object.

4. The method according to claim 1, wherein the target contour is specified as a specified value of a structure result to be achieved in the projection lithography.

5. A method for qualifying a defect structure on an object utilizable in projection lithography, comprising the following steps:
specifying a maximum target difference between an intensity maximum and an intensity minimum of a measured intensity value when imaging a region of interest (ROI) of the object as a tolerance limit,
imaging the ROI of the object for detecting an image field corresponding to the ROI, having measured intensity values assigned to the image field points,
determining a maximum part-field actual difference between an intensity maximum and an intensity minimum of a measured intensity value, present in each case in part-fields of the image field, when imaging the respective part-field,
comparing the respective part-field actual difference with the target difference for all part-fields, and
defining the defect structure as the sum of all part-fields in which the part-field actual difference is greater than the target difference.

6. The method according to claim 5, wherein the maximum target difference is surrounded based on an intensity noise value.

7. The method according to claim 5, comprising the following further steps:
specifying a minimum extent of a qualified defect structure,
comparing an extent of the defect structure with the specified minimum extent, and
outputting the defined defect structure as a qualified defect structure if the extent of the defined defect structure is greater than the minimum extent.

8. A software product for carrying out a program sequence corresponding to a method according to claim 1.

9. A metrology system for carrying out a method according to claim 1.

10. The method of claim 2, wherein the target contour is specified as the mean value of a plurality of object structures measured in the context of a preliminary inspection of the object.

11. The method of claim 2, wherein the target contour is specified as a specified value of a structure result to be achieved in the projection lithography.

12. The method of claim 6, comprising:
specifying a minimum extent of a qualified defect structure,
comparing an extent of the defect structure with the specified minimum extent, and
outputting the defined defect structure as a qualified defect structure if the extent of the defined defect structure is greater than the minimum extent.

13. The software product of claim 8, wherein the target contour is specified in the context of a preliminary inspection of the object by measuring a structure which is qualified as defect-free in the context of the preliminary inspection.

14. The software product of claim 8, wherein the target contour is specified as the mean value of a plurality of object structures measured in the context of a preliminary inspection of the object.

15. The metrology system of claim 9, wherein the target contour is specified in the context of a preliminary inspection of the object by measuring a structure which is qualified as defect-free in the context of the preliminary inspection.

16. The metrology system of claim 9, wherein the target contour is specified as the mean value of a plurality of object structures measured in the context of a preliminary inspection of the object.

17. The metrology system of claim 9, wherein the target contour is specified as a specified value of a structure result to be achieved in the projection lithography.

18. A software product for carrying out a program sequence corresponding to a method according to claim 5.

19. A metrology system for carrying out a method according to claim 5.

20. The metrology system of claim 19. wherein the target contour is specified in the context of a preliminary inspection of the object by measuring a structure which is qualified as defect-free in the context of the preliminary inspection.
